(19) United States
(12) Patent Application Publication
(10) Pub. No.: US 2020/0081505 A1
(43) Pub. Date: Mar. 12, 2020

(54) THERMAL MODULES WITH CONDUCTIVE COVER PLATES

(71) Applicant: HEWLETT-PACKARD DEVELOPMENT COMPANY, L.P., SPRING, TX (US)

(72) Inventors: XIANG MA, SPRING, TX (US); PAUL R LALINDE, SPRING, TX (US); BAOSHENG ZHANG, SPRING, TX (US); JAMIL A WAKIL, SPRING, TX (US)

(21) Appl. No.: 16/469,638

(22) PCT Filed: Apr. 21, 2017
(86) PCT No.: PCT/US2017/028778

§ 371 Date: Jun. 13, 2019

(51) Int. Cl. G06F 1/20; H05K 7/20

(52) U.S. Cl. CPC G06F 1/203; H05K 7/20145; G06F 1/1616; H05K 7/20154; H05K 7/20336; H05K 7/20172

(57) ABSTRACT

In an example, a thermal module may include a conductive cover plate, a fan attached to the conductive cover plate, and a flow channel attached to the conductive cover plate downstream from the fan. The flow channel may direct airflow from the fan to an air outlet of the thermal module. The thermal module may be attachable as a single unit to the electronic device.

### BACKGROUND

Electronic devices may include electronic components that may increase in temperature during use. The temperature of the electronic components may increase to such a degree that the temperature might inhibit optimal performance of the electronic component, cause unreliable operation of the electronic component, reduce usable lifetime of the electronic component, or even cause damage to the electronic component, nearby components, or the entire electronic device as a whole. Such electronic components may be coupled to heat transfer components in order to decrease, or regulate, the temperature of such a component to avoid damage or loss of performance quality. Such heat transfer components may include conductive or convective components, such as heat sinks or air and/or liquid cooling devices, which may enable thermal energy to be transferred from the electronic component to a fluid surrounding or flowing through or over the heat transfer component.

### BRIEF DESCRIPTION OF THE DRAWINGS

FIG. 1 is a perspective view of an example thermal module.

FIG. 2 is a perspective view of an example thermal module.

FIG. 3 is a perspective view of an example thermal module.

FIG. 4A is a perspective view of an example system board assembly having an example thermal module.

FIG. 4B is a perspective view of an example system board assembly having an example thermal module.

FIG. 5A is a top perspective view of an example electronic device having an example thermal module.

FIG. 5B is a bottom perspective view of an example electronic device having an example thermal module.

### DETAILED DESCRIPTION

Electronic devices, such as computing devices for example, may include electronic components that may generate thermal energy, or, in other words, may get hot or increase in temperature, during use. Such electronic components may be referred to as heat-generating components. The electronic components may be computing components, such as processors, integrated circuits, application-specific integrated circuits (ASIC's), or, further, may include optical components or memory or storage components. The temperature of the electronic components may increase to such a degree that the temperature might inhibit optimal performance of the electronic component, cause unreliable operation of the electronic component, reduce usable lifetime of the electronic component, or even cause damage to the electronic component, nearby components, or the electronic device as a whole. Such electronic components may be coupled to heat transfer components in order to decrease, or regulate, the thermal energy, and thus, the temperature of such a component to avoid damage or loss of performance quality. Such heat transfer components may include heat exchangers including conductive and/or convective components such as heat sinks, and air and/or liquid cooling devices, which may enable thermal energy to be transferred from the electronic component to a fluid surrounding or flowing through or over the heat transfer component.

In some situations, thermal energy may be transferred from an electronic component and removed from the electronic device within which the electronic component is disposed by a cooling device that may deliver or draw air or another cooling fluid over the electronic component. Such a cooling device may be a fan, and may be disposed within the electronic device along with the electronic component. Fans may be used in conjunction with other or additional heat transfer components, for example, heat sinks, fins, heat exchangers, heat pipes, and/or vapor chambers. The fan and any other heat transfer components used in conjunction with the fan may each be individually mounted and installed into the electronic device in a respective appropriate location in order to define a cooling system to cool the electronic device, or components within. Such individual mounting and installation of the heat transfer components may utilize multiple or numerous sealing locations in order to obtain a desired cooling function and/or efficiency.

In some situations, the mounting and installation of multiple heat transfer components within an electronic device in an individual manner may be overly complicated and delicate, due to such numerous sealing locations. Further, the heat transfer components may be sealed against the inside of an external case, cover, or housing of the electronic device, which may make servicing and/or disassembly of the electronic device difficult, or such disassembly and/or servicing may render the cooling system and/or the heat transfer components thereof, less efficient or effective after reassembling the electronic device, as the integrity of such sealing locations may be compromised by the disassembly and reassembly process.

Implementations of the present disclosure provide thermal modules that may transfer thermal energy from a heat-generating component within an electronic device. Example thermal modules disclosed herein may include multiple heat transfer components that may be arranged in and/or assembled as a standalone modular unit, which may be installed or removed from the electronic device as a whole. Such a standalone, singular unit may simplify the installation process and minimize the number of thermal sealing locations used in the cooling system of the electronic device. Additionally, implementations of the present disclosure may provide thermal modules which may maintain a high degree of cooling performance and/or efficiency, even after a servicing or disassembly operation has been performed on the electronic device.

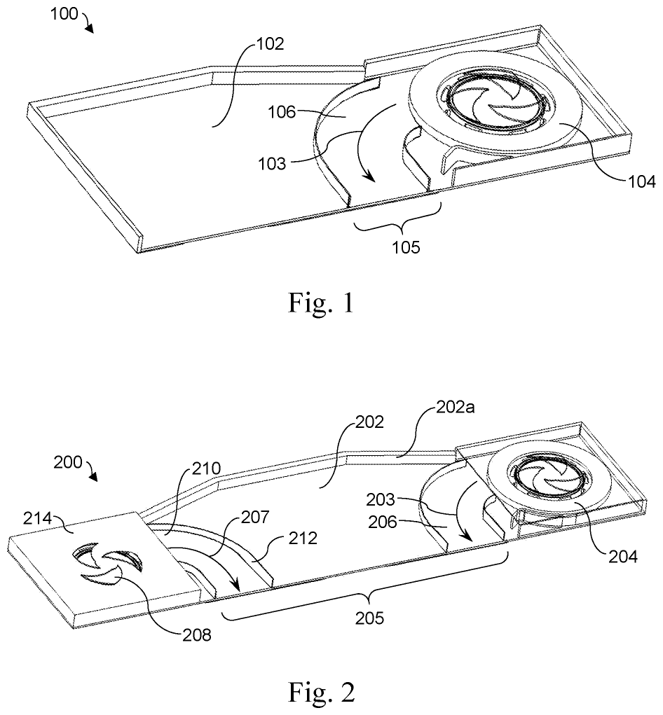

Referring now to FIG. 1, a perspective view of an example thermal module 100 is illustrated. Thermal module 100 may include a conductive cover plate 102, a fan 104 attached to the conductive cover plate 102, and a flow channel 106 attached to the conductive cover plate 102 downstream from the fan 104. The flow channel 106 may direct, divert, or otherwise control an airflow from the fan 104 to an air outlet 105 of the thermal module 100. The conductive cover plate 102 may contact, attach to, or otherwise engage with a heat-generating component (or any other hot component or component that may benefit from having thermal energy transferred away from it) of an electronic device if the thermal module 100 is installed in such an electronic device, which may be a computing device, in some implementations. In some implementations, the thermal module 100 may be attachable or installable (and/or detachable or removable) as a single or singular unit or module to the electronic device.

The conductive cover plate 102 may be an integrating support component to which multiple other components of the thermal module 100 may be attached or assembled. Thus, in some implementations, the conductive cover plate 102 may define the single, unitary, and/or modular nature of the thermal module 100. In some implementations, the conductive cover plate 102 may be a housing or support frame or structure for such other components, or a portion thereof. Further, the conductive cover plate 102 may be a sheet or panel suitably sized and constructed to support the other components of the thermal module 100. The conductive cover plate 102 may include or be constructed of a thermally conductive material or another material which may efficiently transfer thermal energy. Such materials may include copper, titanium, aluminum, steel, magnesium aluminum (MgAl), magnesium lithium (MgLi), alloys thereof, or other thermally conductive or heat-dissipating materials. In further implementations, the conductive cover plate 102 may not be entirely thermally conductive, but rather may have specific portions or sections that are more thermally conductive than the other portions of the cover plate. In some implementations, the conductive cover plate 102 may be a vapor chamber or heat pipe, or a portion of a vapor chamber or heat pipe. In this context, vapor chambers and heat pipes may refer to devices that utilize thermal conductivity and/or phase transition of a working fluid to manage the transfer of thermal energy across the device or along a length of the device. In yet further implementations, the conductive cover plate 102 may be a thermal charger to convert thermal energy into electrical energy, wherein such electrical energy may be used by other components in the system, such as a battery.

The fan 104 may be a device for moving a working fluid, such as air. The working fluid may be delivered through, along, or around the thermal module 100 in order to convectively transfer thermal energy. In some implementations, the fan 104 may have a plurality of blades or vanes arranged in a rotary fashion, such that upon the fan spinning, the blades or vanes may displace or move air. In some implementations, the fan 104 may be rotated or motivated by a motive element, such as an electric motor. In the illustrated implementation, the fan 104 may displace or move air so as to cause the air to move in an airflow through an interior volume of the thermal module 100. It should be noted that, while the fan 104 may be described herein as being a device to move atmospheric air or another gaseous fluid, it is contemplated that implementations of the present disclosure may utilize a pump or another device to move a liquid working fluid through an example thermal module instead of a gaseous working fluid. In yet further implementations, the working fluid may have both liquid and gaseous properties, such as a saturated vapor.

The flow channel 106 may be a structure partially or wholly within the thermal module 100 and suitable to direct, divert, or otherwise aim or control an airflow from the fan 104. In some implementations, the flow channel 106 may be defined by sidewalls, baffles, trenches, slots, and/or any other geometry or members suitable to divert the airflow from the fan 104 in a desired direction to a desired terminal point, such as an air outlet. In some implementations, the flow channel 106 may be structured so as to direct the airflow from the fan 104 along a direction similar to direction 103. In further implementations, the flow channel 106 may direct the airflow from the fan 104 to the air outlet 105. The air outlet 105 may have a size and/or location within the thermal module 100 other than illustrated in FIG. 1.

Referring now to FIG. 2, a perspective view of an example thermal module 200 is illustrated. Example thermal module 200 may be similar to example thermal module 100. Further, the similarly-named elements of example thermal module 200 may be similar in function and/or structure to the respective elements of example thermal module 100, as they are described above. In some implementations, example thermal module 200 may include a fan 204, a flow channel 206, and a conductive cover plate 202. Further, the thermal module 200 may include a second fan 208. In such an implementation, the fan 204 may be referred to as a first fan 204. Second fan 208 may be similar in structure and/or function to the first fan 204. Additionally, each of the first fan 204 and the second fan 208 may include a fan cover 214. The fan cover disposed over the first fan 204 is illustrated as transparent or see-through in FIG. 2 for clarity. The first fan 204 may be disposed at a first end or portion of the conductive cover plate 202, and the second fan 208 may be disposed at a second end or portion of the conductive cover plate 202, which may be spaced away from the first end. Thus, the first fan 204 and the second fan 208, in some implementations, may be spaced apart from each other.

In some implementations, the first fan 204 and the second fan 208 may both deliver or drive air (in the form of an airflow) along a single flow channel to an air outlet 205 of the thermal module 200. In other words, the first fan 204 may deliver or direct air along a flow channel within the thermal module, and the second fan 208 may also direct air along the same flow channel, or a portion thereof. In other implementations, each of the first fan 208 and the second fan 208 may deliver an airflow through a separate flow channel. In the illustrated example, the first fan 204 may deliver or direct air or an airflow through or along the first flow channel 206, which may divert or direct the airflow in a direction similar to direction 203. Further, the thermal module 200 may include a second flow channel 210 located downstream from the second fan 208, the second fan 208 to deliver or direct air or an airflow through or along the second flow channel 210, which may divert or direct the airflow in a direction similar to direction 207. In some implementations the first flow channel 206 and the second flow channel 210 may have a similar structure and function, and may be substantial mirror images of one another. Thus, the first fan 204 and the second fan 208 may spin in opposite directions to each other in order to deliver air similar to the illustrated manner along the respective flow channels. In other implementations, the first flow channel 206 and the second flow channel 210 may divert or direct airflow to the air outlet 205 in a different direction than as illustrated, yet still toward an air outlet of the thermal module 200.

In some implementations, each of the first flow channel 206 and the second flow channel 210 may have a sidewall 212 or multiple sidewalls 212 to direct airflow from the respective fan to the air outlet 205. Such sidewalls 212 may partially or wholly define the structure and/or flow direction of the respective flow channel. Further, one or both of the first flow channel 206 and/or the second flow channel 210 may have a conductive sidewall 212 that may extend from, or be attached to the conductive cover plate 202. Thus, in some implementations of the present disclosure, thermal energy which may be present in the conductive cover plate 202 may be conductively transferred to conductive sidewalls 212 of the first and second flow channels. First fan 204 and second fan 208 may each deliver an airflow through the first flow channel 206 and the second flow channel 210, respectively, and such airflows may convectively transfer thermal energy from the sidewalls 212 of the flow channels to the air outlet 205 to remove the thermal energy from the thermal module 200.

In further implementations, the conductive cover plate 202 may have sidewalls 202a that extend, at least partially, around a perimeter or outer edge of the conductive cover plate 202. In some implementations, the sidewalls 202a may not be conductive, or may inhibit or prevent the transfer of thermal energy from within the thermal module 200 to outside the thermal module 200 such that thermal energy may only be transferred out of the air outlet 205.

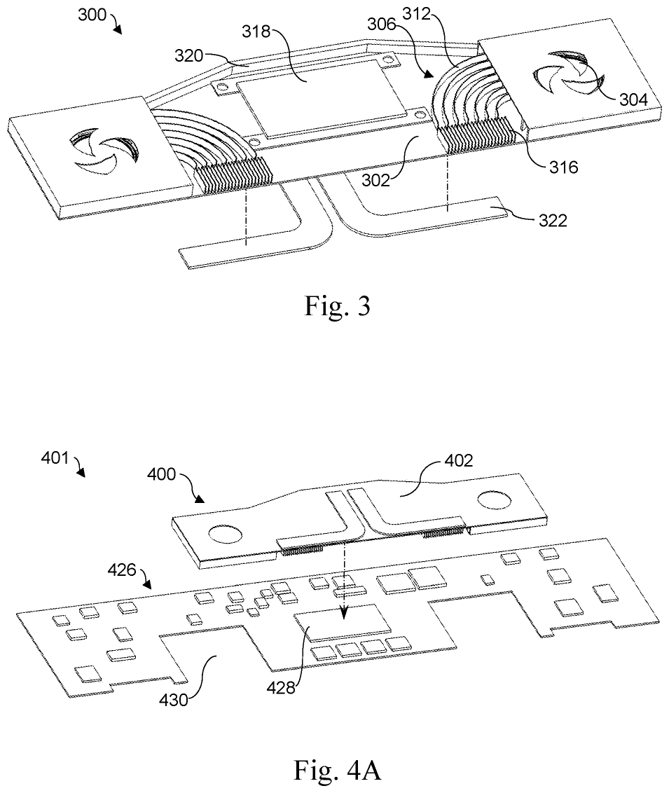

Referring now to FIG. 3, a perspective view of an example thermal module 300 is illustrated. Example thermal module 300 may be similar to example thermal modules described above. Further, the similarly-named elements of example thermal module 300 may be similar in function and/or structure to the respective elements of other example thermal modules, as they are described above. In some implementations, the thermal module 300 may include a thermal plate 318. The thermal plate 318 may be assembled, attached, or fixed to a conductive cover plate 302 of the thermal module 300. In some implementations, the thermal plate 318 may be welded, soldered, or brazed, at least partially, to the conductive cover plate 302. The thermal plate 318 may be a sheet or plate constructed of a conductive material such that the thermal plate 318 may transfer thermal energy to the conductive cover plate 302. In some implementations, the thermal plate 318 may engage with a heat-generating component (or another component with excess thermal energy) of an electronic device to which the thermal module 300 may be assembled so as to transfer thermal energy from the heat-generating component to the conductive cover plate 302. In further implementations, the thermal plate 318 may be a vapor chamber.

In some implementations, the thermal module 300 may include a fan 304 and a flow channel 306. The flow channel 306 may include a plurality of conductive fins 312 attached to or extending from the conductive cover plate 302. Thus, the conductive cover plate 302 may conductively transfer thermal energy to the plurality of fins 312, which may be sized, oriented, and spaced sufficiently to transfer the thermal energy at a desired rate to the flow channel 306, and/or airflow within. In some implementations, the thermal module 300 may include a second fan and a second flow channel having a plurality of fins, or any number of fans and corresponding flow channels, but for brevity only fan 304 and flow channel 306 will be discussed herein. The fan 304 may deliver the airflow through the flow channel 306 so as to convectively transfer thermal energy from the plurality of conductive fins 312 to an air outlet of the thermal module 300. Stated differently, the flow channel 306 having the plurality of conductive fins 312 may direct airflow from the fan 304 to the air outlet. In further implementations, the thermal module 300, or the flow channel 306 thereof, may have a second plurality of conductive fins 316 extending from or attached to the conductive cover plate 302. The second plurality of conductive fins 316 may be disposed in the flow channel 306 and at or near the air outlet of the thermal module 300. The second plurality of conductive fins 316 may be sized and spaced suitably to as to enable the efficient transfer of thermal energy from the conductive cover plate 302 to the airflow from the fan 304.

The example thermal module 300 may further include a heat pipe 322 (illustrated as partially exploded) to transfer thermal energy from the thermal plate 318 to the plurality of conductive fins 312 of the flow channel 306. In other words, the heat pipe 322 may be disposed on the conductive cover plate 302 and extend from a portion of the conductive cover plate 302 disposed near the thermal plate to a portion of the conductive cover plate 302 disposed near the flow channel 306. Stated in yet another way, if the thermal module 300 is installed or attached to an electronic device, the thermal plate 318 may be thermally engaged with a heat-generating component (or any component with excess thermal energy), and therefore the heat pipe 322 may transfer thermal energy from a portion of the conductive cover plate 302 disposed near the heat-generating component to a portion of the conductive cover plate 302 disposed near the flow channel 306, or, further, near the air outlet. In some implementations, the heat pipe 322 may extend from the heat-generating component to the portion of the conductive cover plate 302 having the second plurality of fins 316. Thus, the heat pipe 322 may assist in transferring thermal energy from the heat-generating component to the flow channel 306, wherein the fan may convectively transfer the thermal energy to and out of the air outlet. In implementations wherein the thermal module 300 includes a first and second fan and a first and second flow channel, the thermal module 300 may also further include a second heat pipe to transfer thermal energy to the second flow channel. In further implementations, the heat pipe 322 and/or the second heat pipe may have a different shape, orientation, or location than as illustrated.

In some implementations, the thermal module 300 may further include a thermal barrier 320. The thermal barrier 320 may be a sealing component constructed of a material that is non-thermally-conductive, or which may inhibit the efficient transfer of thermal energy. In some implementations, the thermal barrier 320 may be constructed of a polymer, rubber, or sponge material to inhibit thermal energy transfer. In further implementations, the thermal barrier 320 may be disposed along a rear edge of the conductive cover plate 302. The rear edge, in some examples, may be an edge opposite from the air outlet. If the thermal module 300 is installed in or attached to an electronic device, or a system board or circuit board thereof, the thermal barrier 320 may engage with or be squeezed against the system board or circuit board so as to seal the rear edge of the conductive cover plate 302 to the system board or circuit board.

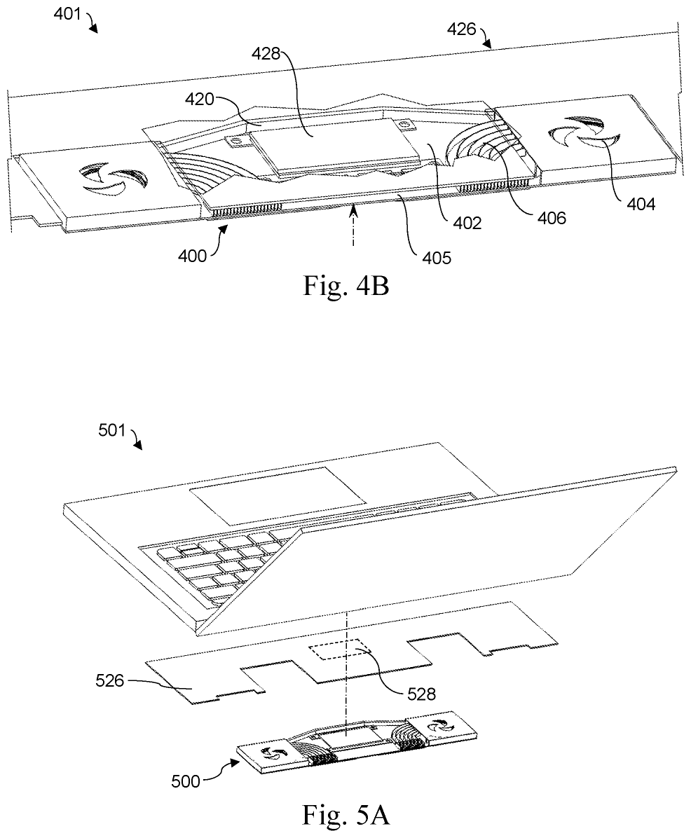

Referring now to FIG. 4A, a perspective view of an example system board assembly 401 having an example thermal module 400 is illustrated. Example thermal module 400 may be similar to example thermal modules described above. Further, the similarly-named elements of example thermal module 400 may be similar in function and/or structure to the respective elements of other example thermal modules, as they are described above. In some implementations, the system board assembly 401 may include a circuit board 426. Circuit board 426 may sometimes be referred to as a system board, or motherboard. Circuit board 426 may structurally support and electrically connect multiple electronic components and/or computing components. The circuit board 426 may, in some implementations, electrically connect multiple electronic components with conductive pathways. In further implementations, the circuit board 426 may be substantially constructed of a non-conductive substrate with copper pathways etched onto the substrate. In some implementations, the non-conductive substrate may include silicon. In some implementations, the circuit board 426 might comprise a single-layer printed circuit board (PCB), or a multi-layer PCB in other implementations. In further implementations, the circuit board 426, or the system board assembly 401, may be referred to as a printed circuit assembly (PCA).

In some implementations, the system board assembly 401, or the circuit board 426 thereof, may include a heat-generating component 428 disposed on or operably attached to the circuit board 426. The heat-generating component 428 may be a component that generates thermal energy during use. In other implementations, the heat-generating component 428 may be a component that is exposed to excess thermal energy from another source, instead of generating the thermal energy itself. In further implementations, the heat-generating component 428 may be any component that may have or be exposed to excess thermal energy, or that may benefit from having thermal energy transferred away from such a component. The heat-generating component may be an electronic component or computing component, such as a processor, central processing unit (CPU), chipset, integrated circuit, ASIC, a memory or data storage component, or another type of electronic or computing component. In addition to the heat-generating component, the system board assembly 401, or the circuit board 426 thereof, may include other electronic components, such as circuits, resistors, capacitors, electrical connectors, or other types of electronic components.

In some implementations, the thermal module 400 may be attachable to and/or detachable from the circuit board 426 as a single unit. In other words, the thermal module 400, and the constituent components thereof, may be a modular, singular, standalone module or component that may be assembled on to the circuit board 426. Thus, the individual components of the thermal module 400, including but not limited to, a fan, a flow channel, and/or a conductive cover plate, do not have to be individually attached to or assembled on to the system board assembly 401, or the circuit board 426 thereof. The individual components of the thermal module 400 may be assembled together to define the thermal module 400 as a standalone unit or component, and the thermal module 400 may then subsequently be assembled on the system board assembly 401, or the circuit board 426 thereof.

In some implementations, the system board assembly 401, or the circuit board 426 thereof, may include a fan cutout 430 to provide clearance for, and at least partially receive a fan 404 of the thermal module 400. In implementations wherein the thermal module 400 has multiple fans, the circuit board 426 may include a corresponding number of fan cutouts.

Referring additionally to FIG. 4B, a cutaway perspective view of the example system board assembly 401 is illustrated wherein the thermal module 400 is operably engaged with or assembled on to the circuit board 426. For clarity, other components which may be disposed on the circuit board 426 in some examples have been omitted, with only the heat-generating component 428 left illustrated, and a portion of the circuit board 426 has been cut away to illustrate the engagement of the heat-generating component 428 with the thermal module 400. Once the thermal module 400 is assembled on to or otherwise operably engaged with the system board assembly 401 and/or the circuit board 426 thereof, a conductive cover plate 402 of the thermal module 400 may be conductively engaged with the heat-generating component 428. Conductively engaged, in this context, may refer to the conductive cover plate 402 engaged with the heat-generating component 428 in such a way so as to be able to receive thermal energy from the heat-generating component 428, or, in other words, may be able to conductively transfer thermal energy from the heat-generating component 428. In some implementations, the conductive cover plate 402 may contact the heat-generating component 428 directly, or, in other implementations, the conductive cover plate 402 may be conductively engaged with the heat-generating component 428 indirectly, such as through an intermediate component like a thermal plate, for example, or through conductive paste or adhesive, in another example. Therefore, in some implementations, the thermal module 400 may further include a thermal plate disposed on the conductive cover plate 402 to conductively engage the heat-generating component 428 with the conductive cover plate 402.

The thermal module 400 may be attached to the circuit board 426 such that the conductive cover plate 402 and the circuit board 426 define a closed volume in between the thermal module 400 and the circuit board 426, through which a flow channel 406 may direct airflow from the fan 404. In other words, the thermal module 400 may attach to the circuit board 426 such that the circuit board 426 directly acts as a side of the closed volume, with no other plates, covers, housings, or panels of the thermal module 400 in between the circuit board 426 and the inner components of the thermal module 400. The conductive cover plate 402, may thus have physical access to and conductively transfer thermal energy from the heat-generating component 428 to the flow channel 406, or conductive fins thereof, and the fan 404 may direct air along the flow channel 406 to convectively transfer the thermal energy out of the thermal module 400. Thus, the thermal module 400 may decrease or regulate the temperature of the heat-generating component 428.

The thermal module 400, or the conductive cover plate 402 thereof, may be at least partially sealed to the circuit board 426 by a thermal barrier 420 in some implementations. The thermal barrier 420 may prevent heat disposed within the closed volume, or the flow channel 406 therein, from escaping to other internal areas of an electronic device within which the system board assembly 401 may be disposed. In further implementations, the thermal barrier 420 may further seal airflow and prevent such airflow from escaping the closed volume to other internal areas of the electronic device. In some implementations, the system board assembly 401, or the circuit board 426 and/or thermal module 400 thereof, may include other components, such as heat spreaders to fill in air gaps to improve heat spreading between the conductive cover plate and other components of the system board assembly 401. In further implementations, an injected and/or expanding foam may be used to fill in the closed volume to further adhere the thermal module 400, or the conductive cover plate 402 thereof, and the circuit board 426. In yet further implementations, the closed volume may actually be partially closed, with the closed volume being left open at an air outlet 405 of the thermal module 400. The flow channel 406 may direct airflow from the fan 404 out of the air outlet 405.

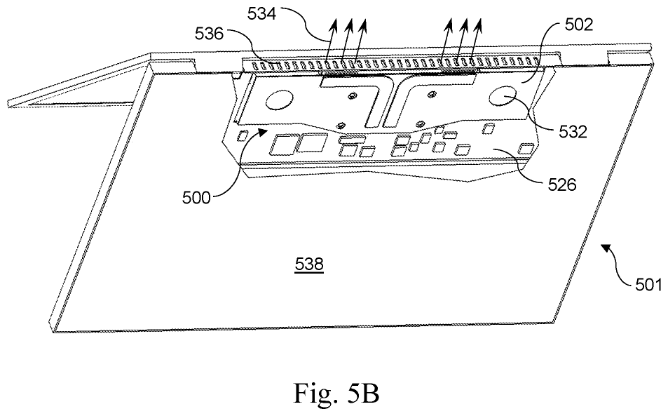

Referring now to FIG. 5A, a top, partially exploded, perspective view of an example electronic device 501 having an example thermal module 500 is illustrated. Example thermal module 500 may be similar to example thermal modules described above. Further, the similarly-named elements of example thermal module 500 may be similar in function and/or structure to the respective elements of other example thermal modules, as they are described above. The electronic device 501 may be any electronic device having a heat-generating component 528 within it that may benefit from having thermal energy transferred from such a component and out of the electronic device. In some implementations, the electronic device may be a computing device, and, in further implementations, the electronic device 501 may be a notebook computer. In some implementations, the electronic device 501 may include a heat-generating component 528 disposed on a system board 526. The heat-generating component 528 may be disposed on an underside of the system board 526, and, thus, is illustrated in phantom. The heat-generating component 528 may be disposed on the same side of the system board 526 to which the thermal module 500 may be attached or assembled.

Referring now to FIG. 5B, a bottom perspective cutaway view of the electronic device 501 is illustrated wherein the thermal module 500 is assembled on to the system board 526, as described above with reference to FIGS. 4A-4B, and the system board 526 is assembled into the electronic device 501. A portion of a bottom cover 538 of the electronic device 501 is cut away to illustrate the thermal module 500 and the system board 501. In some implementations, the electronic device 501 may include a thermal exhaust 536, which may be disposed on an exterior surface, case, and/or housing of the electronic device 501. The thermal exhaust 536 may be oriented so as to be adjacent or near an air outlet of the thermal module 500.

The thermal module 500 may be conductively engaged with the heat-generating component 528 (not shown in FIG. 5B) such that a conductive cover plate 502 may transfer thermal energy from the heat-generating component 528 to a flow channel within the thermal module 500, which may be operably engaged with a fan of the thermal module 500. The fan may draw air in through an air inlet 532 in the conductive cover plate 502, and send, blow, or otherwise direct the air, in the form of an airflow, along the flow channel to convectively transfer the thermal energy within the flow channel out of the air outlet and, correspondingly, out of the thermal exhaust 536. Stated differently, the flow channel may have components such as conductive sidewalls or fins attached to the conductive cover plate 502 to direct airflow from the fan to the thermal exhaust 536 of the electronic device 501. Such exhaust or convective transfer of the thermal energy may be represented by example arrows 534 in FIG. 5B.

What is claimed is:

1. A thermal module, comprising:
a conductive cover plate to engage with a heat-generating component of an electronic device;
a fan attached to the conductive cover plate; and
a flow channel attached to the conductive cover plate downstream from the fan, the flow channel to direct airflow from the fan to an air outlet of the thermal module,
wherein the thermal module is attachable as a single unit to the electronic device.

2. The thermal module of claim 1, wherein the flow channel includes a plurality of conductive fins attached to the conductive cover plate.

3. The thermal module of claim 1, further comprising a second fan to direct air along the flow channel.

4. The thermal module of claim 3, further comprising a second flow channel located downstream from the second fan, the second fan to direct air along the second flow channel.

5. The thermal module of claim 1, further comprising a thermal plate to engage with a heat-generating component of the electronic device so as to transfer thermal energy from the heat-generating component to the conductive cover plate.

6. The thermal module of claim 5, wherein the thermal plate is a vapor chamber.

7. The thermal module of claim 1, wherein the fan is to draw air in through an air inlet in the conductive cover plate.

8. A system board assembly, comprising:
a circuit board;
a heat-generating component disposed on the circuit board; and
a thermal module attachable to the circuit board as a single unit, the thermal module comprising:
a conductive cover plate to conductively engage with the heat-generating component,
a fan attached to the conductive cover plate; and
a flow channel having a plurality of conductive fins attached to the conductive cover plate to direct airflow from the fan to an air outlet of the thermal module;
wherein the thermal module is attached to the circuit board such that the conductive cover plate and the circuit board define a closed volume through which the flow channel directs airflow from the fan.

9. The system board assembly of claim 8, wherein the thermal module further comprises a thermal barrier to seal the thermal module to the circuit board.

10. The system board assembly of claim 8, wherein the circuit board comprises a fan cutout to receive a portion of the fan.

11. The system board assembly of claim 8, wherein the thermal module further comprises a thermal plate disposed on the conductive cover plate to conductively engage the heat-generating component with the conductive cover plate.

12. A computing device, comprising:
a heat-generating component disposed on a system board;
a thermal exhaust; and
a thermal module detachable from the system board as a single unit, the thermal module comprising:
a conductive cover plate to receive thermal energy from the heat-generating component;
a fan attached to the conductive cover plate; and
a flow channel having conductive sidewalls attached to the conductive cover plate to direct airflow from the fan to the thermal exhaust;
wherein the thermal module is attached to the circuit board such that the cover plate and the system board define a closed volume through which the flow channel directs airflow from the fan.

13. The computing device of claim 11, wherein the thermal module further comprises a thermal barrier disposed along a rear edge of the conductive cover plate to engage with the system board so as to seal the rear edge to the system board.

14. The computing device of claim 12, wherein the thermal module further comprises a heat pipe to transfer thermal energy from a portion of the conductive cover plate disposed near the heat-generating component to a portion of the conductive cover plate disposed near the flow channel.

15. The computing device of claim 12, wherein the computing device is a notebook computer.
